(19) United States
(12) Patent Application Publication
(10) Pub. No.: US 2022/0093740 A1
(43) Pub. Date: Mar. 24, 2022

(54) HIGH-POWER FIELD-EFFECT TRANSISTOR (FET)

(71) Applicant: QUALCOMM Incorporated, San Diego, CA (US)

(72) Inventor: Abhijeet PAUL, Escondido, CA (US)

(21) Appl. No.: 17/410,513

(22) Filed: Aug. 24, 2021

Related U.S. Application Data
(60) Provisional application No. 63/080,527, filed on Sep. 18, 2020.

(51) Int. Cl. H01L 29/08; H01L 29/06; H01L 29/78; H01L 29/66; H01L 21/8234

(52) U.S. Cl. CPC H01L 29/0852; H01L 29/063; H01L 21/823412; H01L 29/7801; H01L 29/66674; H01L 29/0696

(57) ABSTRACT

Disclosed are apparatuses and related methods for fabrication. The apparatus includes a field-effect transistor (FET). The FET has a source contact coupled to a source implant in a body layer, a drain contact coupled to a drain implant in the body layer, and a first gate coupled to a transistor channel in the body layer between the source contact and the drain contact. The FET further includes a second gate coupled to the body layer between the source contact and the drain contact, a drift region in the body layer, where the second gate at least partially overlaps the drift region, and a resurf portion disposed partially over the first gate and over the second gate.

### FIELD OF DISCLOSURE

The present Application for Patent claims the benefit of U.S. Provisional Application No. 63/080,527, entitled “POWER SWITCH FIELD-EFFECT TRANSISTOR (FET)” filed Sep. 18, 2020, assigned to the assignee hereof, and expressly incorporated herein by reference in its entirety.

### FIELD OF DISCLOSURE

The present disclosure relates generally to semiconductor devices, and more specifically, but not exclusively, to devices including power switch field-effect transistors (FETs), multi-gate composite FETs, metal-oxide-semiconductor FETs (MOSFETs) and fabrication techniques thereof.

### BACKGROUND

Integrated circuit (IC) technology has achieved great strides in advancing computing power through miniaturization of active components. The reduced size, line spacing, layer height, etc. may create challenges in fabricating and operating devices, such as FETs with high breakdown voltages, which may be used in the radio frequency (RF) amplifier, power switching, and other such demanding applications. Conventional FET designs using thin silicon on insulator (SOI) material (e.g., ˜70 nm) in RFSOI fabrication processes do now allow for the operating at higher voltages (e.g., Vdd=5V). The conventional FETs have a maximum of 3.63V for gate length (Ldes) of ˜0.5 um, with a breakdown voltage (BVD) of 4V, for a given process technology. However, for many RF applications, FETs with voltage handling capability in the range of 5V to 6V for both analog and RF applications are needed. Although FETs can be implemented using other fabrication processes, FETs in using the same SOI process provide much tighter integration with the RF front end (RFFE) IC designs.

Accordingly, there is a need for systems, apparatuses and methods that overcome the deficiencies of conventional FET designs including the methods, systems and apparatuses provided herein in the following disclosure.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In accordance with the various aspects disclosed herein, at least one aspect includes, an apparatus including a field-effect transistor (FET). The FET has a source contact coupled to a source implant in a body layer, a drain contact coupled to a drain implant in the body layer, and a first gate coupled to a transistor channel in the body layer between the source contact and the drain contact. The FET further includes a second gate coupled to the body layer between the source contact and the drain contact, a drift region in the body layer, where the second gate at least partially overlaps the drift region, and a resurf portion disposed partially over the first gate and over the second gate.

In accordance with the various aspects disclosed herein, at least one aspect includes, a method for fabricating an apparatus including a field-effect transistor (FET). The method includes forming a source contact coupled to a source implant in a body layer, forming a drain contact coupled to a drain implant in the body layer, and forming a first gate coupled to a transistor channel in the body layer between the source contact and the drain contact. The method further includes forming a second gate coupled to the body layer between the source contact and the drain contact, forming a drift region in the body layer, where the second gate at least partially overlaps the drift region, and forming a resurf portion disposed partially over the first gate over the second gate.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 illustrates a partial cross-sectional view of a FET in accordance with one or more aspects of the disclosure.

FIG. 2A illustrates a partial top view of an apparatus including a plurality of FETs in accordance with one or more aspects of the disclosure.

FIG. 2B illustrates a cross-sectional view of the apparatus at line A-A′ in FIG. 2A in accordance with one or more aspects of the disclosure.

FIG. 2C illustrates a partial top view of the apparatus including a plurality of FETs in accordance with one or more aspects of the disclosure.

FIG. 2D illustrates a cross-sectional view of the apparatus at line B-B′ in FIG. 2C in accordance with one or more aspects of the disclosure.

FIG. 2E illustrates a partial top view of the apparatus including a plurality of FETs in accordance with one or more aspects of the disclosure.

FIG. 2F illustrates a cross-sectional view of the apparatus at line C-C′ in FIG. 2E in accordance with one or more aspects of the disclosure.

FIG. 3 illustrates a partial top view of an apparatus including a plurality of FETs in accordance with one or more aspects of the disclosure.

FIG. 4 illustrates a partial top view of an apparatus including a plurality of FETs in accordance with one or more aspects of the disclosure.

FIG. 5 illustrates a partial top view of an apparatus including a plurality of FETs in accordance with one or more aspects of the disclosure.

FIG. 6 illustrates a partial top view of an apparatus including a plurality of FETs in accordance with one or more aspects of the disclosure.

FIG. 7 illustrates a partial top view of an apparatus including a plurality of FETs in accordance with one or more aspects of the disclosure.

FIG. 8A is a graph illustrating the breakdown voltage of a nFET in accordance with one or more aspects of the disclosure.

FIG. 8B is a graph illustrating the breakdown voltage of a pFET in accordance with one or more aspects of the disclosure.

FIG. 9 illustrates components of an integrated device in accordance with one or more aspects of the disclosure.

FIG. 10 illustrates a flowchart of a method for fabricating a device in accordance with one or more aspects of the disclosure.

FIG. 11 illustrates an exemplary mobile device in accordance with one or more aspects of the disclosure.

FIG. 12 illustrates various electronic devices that may be integrated with any of the aforementioned apparatuses in accordance with one or more aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

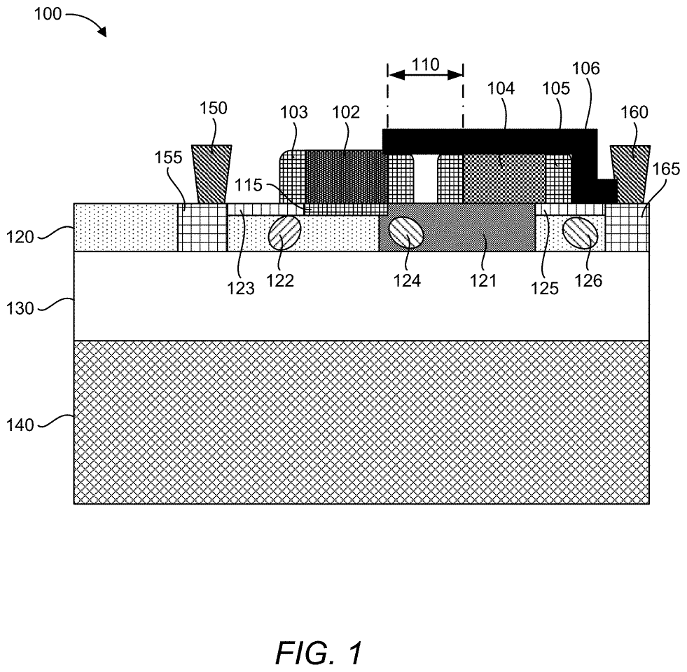

FIG. 1 illustrates a partial cross-sectional view of a FET 100 in accordance with one or more aspects of the disclosure. As illustrated, a handle substrate 140 is provided for fabrication handling and support. In some aspects, the handle substrate 140 may be thinned down to a desired thickness during the fabrication process. The handle substrate 140 may be formed from silicon (Si), glass, aluminum nitride (AlN), sapphire, Group III-V, II-VI semiconductor materials, or any other suitable substrate material. An insulator 130 is disposed on the handle substrate 140. In some aspects, the insulator may have a thickness/height in the range of 20 nm to 1 um. A body layer 120 may be disposed on the insulator 130. The body layer 120 may be p-type silicon or n-type silicon. The body layer 120 may have a thickness/height in the range of 10 to 100 nm. The source contact 150 is formed on a source implant 155 formed in the body layer 120 and in some configurations may be electrically coupled to the transistor channel 115. A drain contact 160 is also formed on a drain implant 165 in the body layer 120 and is electrically coupled to the transistor channel 115. The transistor channel 115 in some aspects can be the same material as the body (e.g., in silicon FETs) or in other aspects can be another material (e.g., silicon germanium (SiGe) in a Si body, etc.).

A first gate 102 is formed on and electrically coupled to the transistor channel 115 in the body layer 120. The first gate 102 may be formed from a polysilicon, metal or other suitable material. A first gate spacer 103 is disposed on the first gate 102 to at least partially enclose the first gate 102. A second gate 104 is formed on and electrically coupled to the body layer 120. The second gate 104 may be formed from a polysilicon, metal or other suitable material. A second gate spacer 105 is disposed on the second gate 104 to at least partially enclose second gate 104. The first gate spacer 103 and second gate spacer 105 may be silicon dioxide(SiO2), silicon nitride (SiN), lowK materials (e.g., silicon boron carbon nitride (SiBCN) and the like) and may be sized on the order of 5-30 nm. As noted the first gate 102 and the second gate 104 may both be formed from polysilicon, metal, etc. However, in other aspects the first gate 102 and the second gate 104 may be formed from different materials, such as poly and metal and with different threshold voltage (Vt) materials (such as replacement metal gate (RMG) process: where different work function metals can be deposited on the two gates 102 and 104 to achieve different threshold voltage (Vt) values and gate leakage to allow for differential channel and drift region electric field control). The first gate 102 and the second gate 104 may be separated from each other by a distance 110, which in some aspects is on the range of 0.09-0.2 um.

A reduced surface field (resurf) portion 106 is disposed over the first gate 102 and second gate 104 and in some aspects may extend to the drain contact 160. Resurf portion106 can be made of materials such as SiN, SiO2, metals, implants. The resurf portion 106 in some aspects may be formed as a salicide block layer and may be formed from silicon nitride (SiN), silicon dioxide(SiO2) a metal (e.g., titanium, cobalt, nickel, platinum and tungsten) cap, oxides, and the like. A drift region 121 is formed in the body layer 120. The drift region 121 may be a lightly doped N+, P+ or intrinsic well implant. The second gate 104 at least partially overlaps the drift region 121. In some aspects, the second gate 104 allows for the control of the electric field in the drift region 121. The body layer 120 also includes a plurality of halo implants including halo implant 122 near the source contact 150, halo implant 126 near the drain contact 160 and optionally halo implant 124 in the drift region. The halo implant 122 on the source side may be different from the halo implant 124 on the drain side to allow for better breakdown voltage (BVD) and on resistance (Ron) trade-offs. For example, the halo implants in some aspects may be two separate implants (asymmetric) configured to provide different voltage handling and Ron trade-off. Additionally, a source extension region 123 is provided adjacent the source contact 150 toward the source implant 155 and a drain extension region 125 is provided adjacent the drain contact 160 toward the drain implant 165.

Table 1 below provides some example ranges and materials for the various elements referenced in FIG. 1. It will be appreciated that these values are provided merely as examples and are not intended to limit the various aspects disclosed herein to any specific value or values.

TABLE 1

| Ref | Dimensions | Material |
|---|---|---|
| 102 | 0.1-1 um | Poly, metal gate, different |
| | | implanted poly gates |
| 103 | 100A-10A | SiO2, HiK material |
| 104 | 0.1-1 um | Poly, metal gate, different |
| | | implanted poly gates |
| 105 | 100A-10A | SiO2, HiK material |
| 106 | 0.2-3 um | SiN, metal plate, SiO2 |
| 110 | 0.09-0.2 um | SiN + SiO2 |
| 120 | 10 nm-100 nm | Si, III-V, II-VI, |
| 121 | | Low value N+ or P+ well implant |
| 122 | | Ptype for nFET, ntype for pFET |
| 123 | | Ptype for pFET, ntype for nFET |
| 124 | | Ptype for nFET, ntype for pFET |
| 125 | | Ptype for pFET, ntype for nFET |
| 126 | | Ptype for nFET, ntype for pFET |
| 130 | 20 nm-1 um | SiO2, insulators |
| 140 | 120-750 um | Si, III-V, II-VI, Glass, AlN |
| 155 | Typical values. | N+ for nFET, P+ for pFET |
| 165 | Typical values. | N+ for nFET, P+ for pFET |

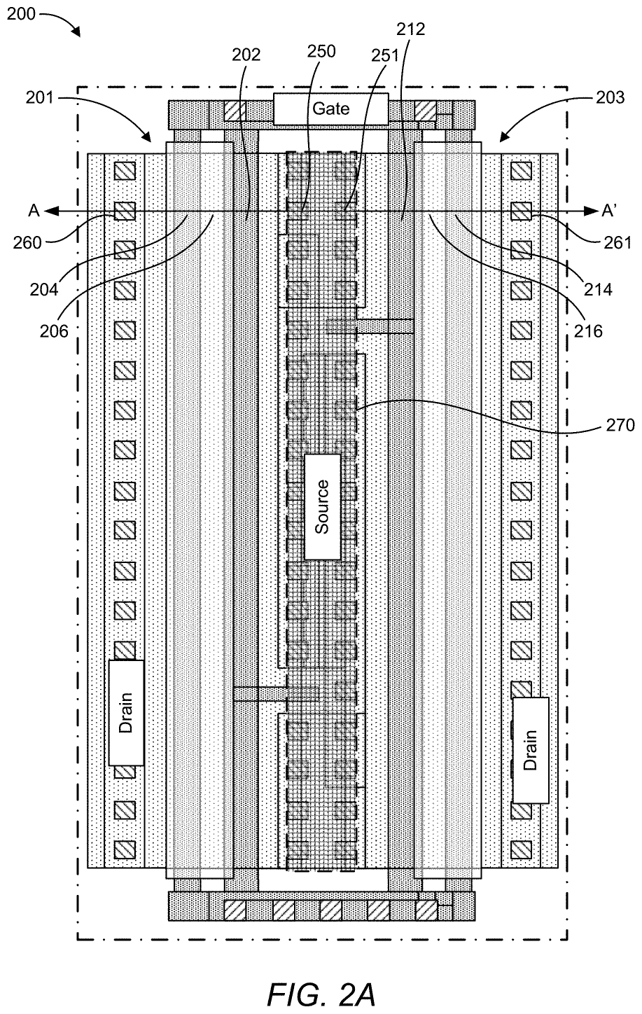

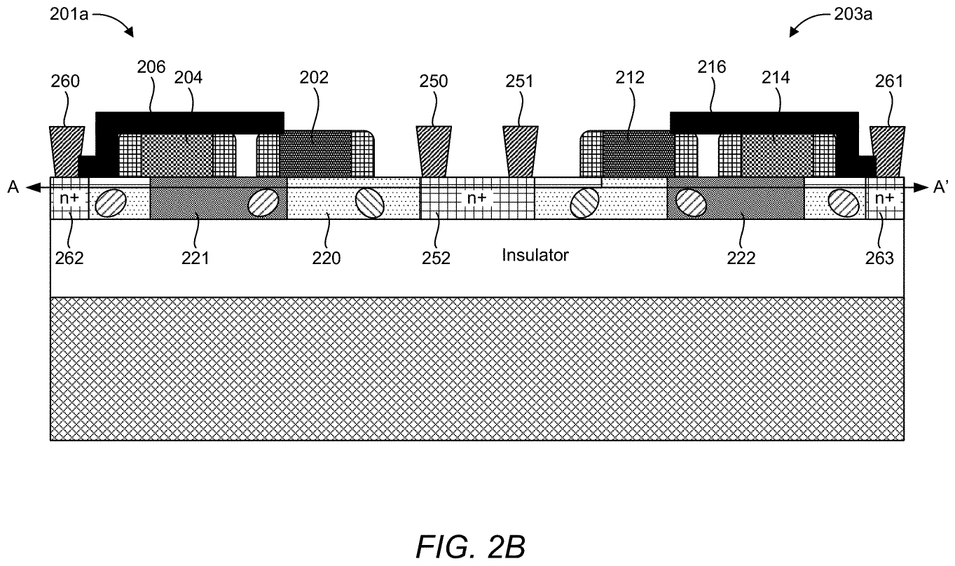

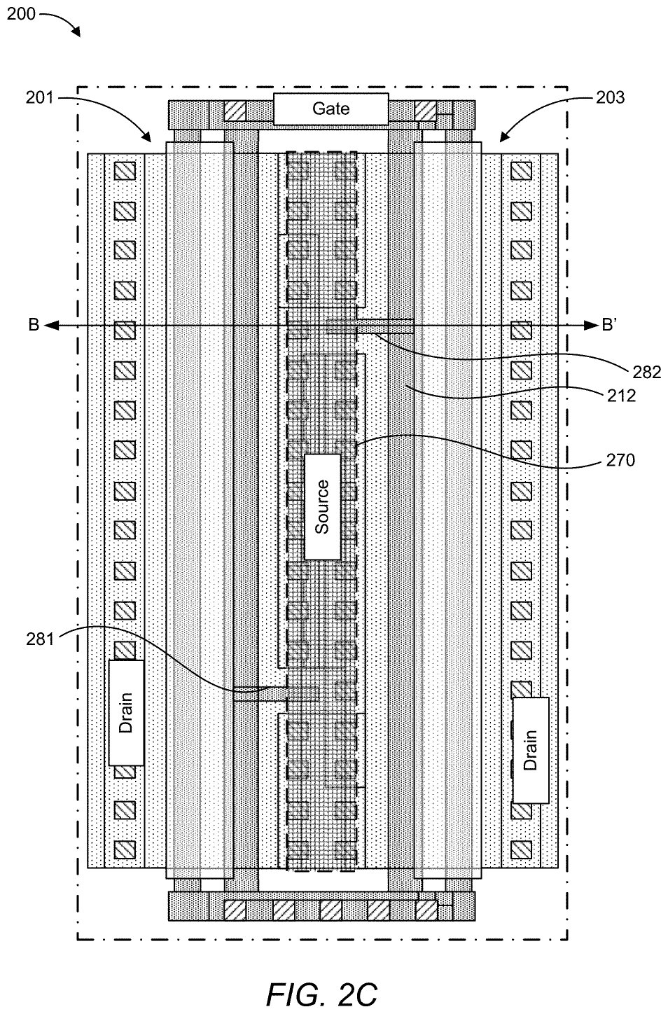

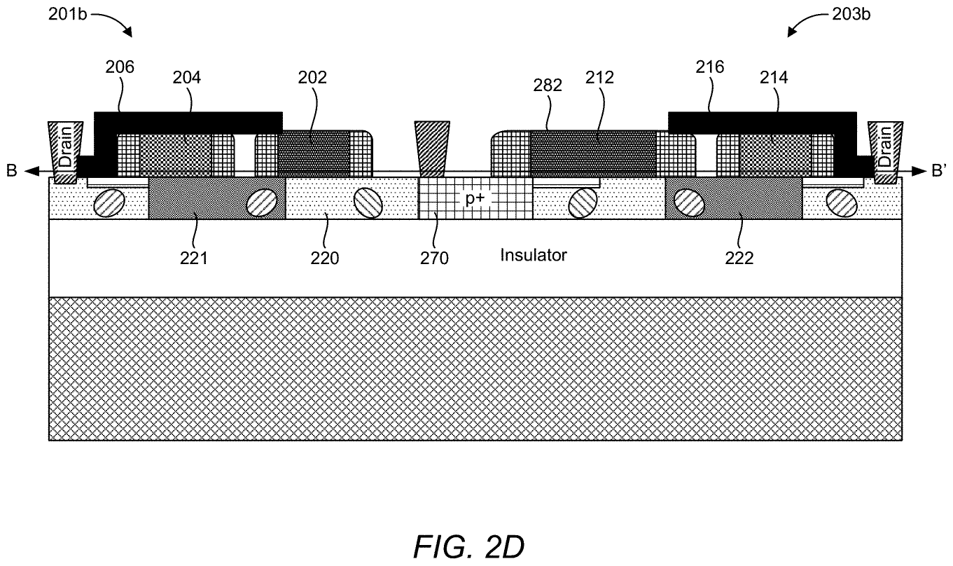

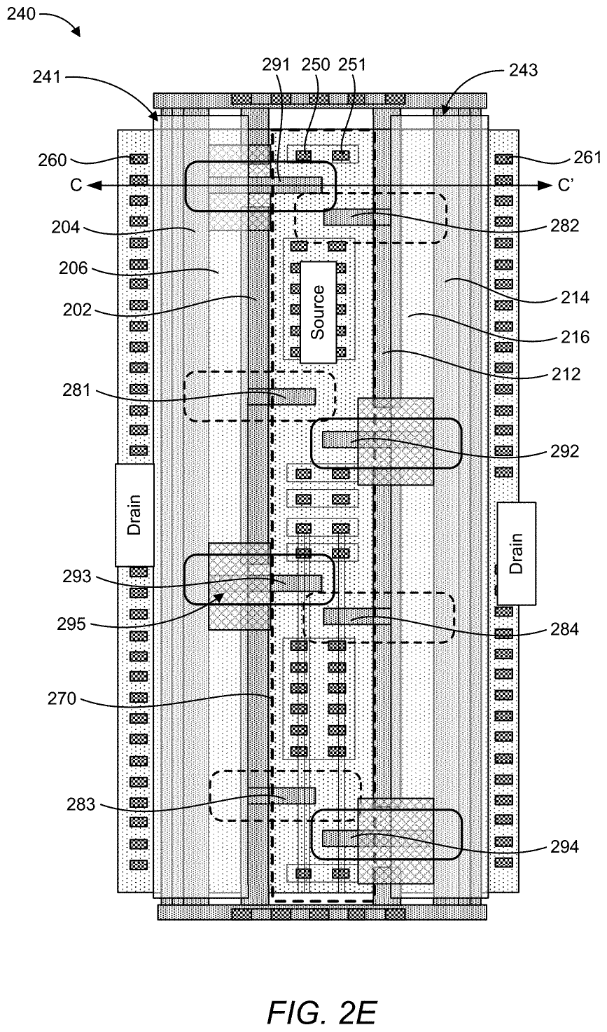

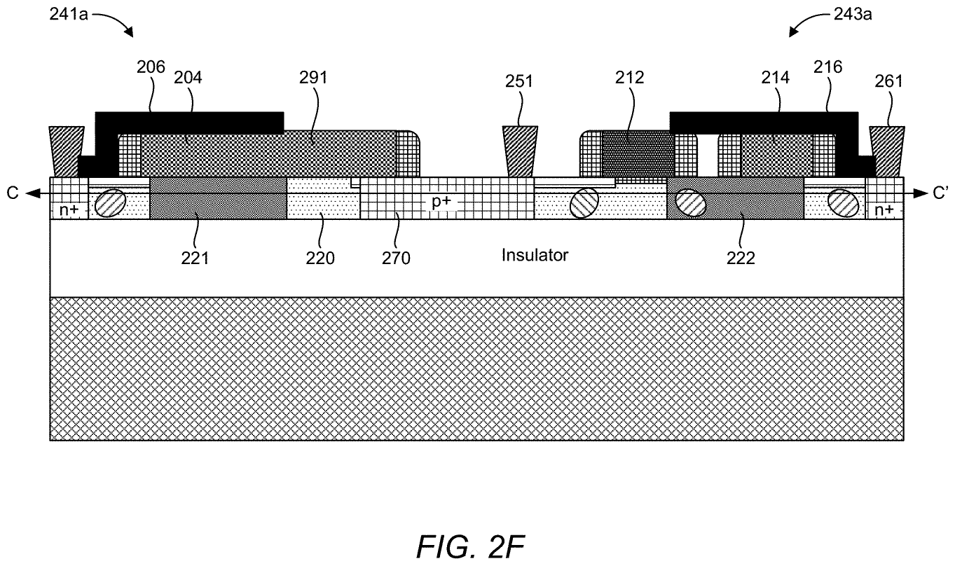

FIG. 2A illustrates a partial top view of an apparatus 200 including a plurality of FETs in accordance with one or more aspects of the disclosure. The apparatus 200 can have a first plurality of FETs 201 arranged in a first column and a second plurality of FETs 203 arranged in a second column. The first plurality of FETs 201 includes drain contacts 260, a first gate 202, a second gate 204, and a resurf portion 206. The resurf portion 206 is disposed partially over the first gate 202 and over the second gate 204 and extends to the drain contacts 260. The first plurality of FETs 201 further includes a plurality of source contacts 250. In the illustrated arrangement, the source contacts 250 of the first plurality of FETs 201 are adjacent a second plurality of source contacts 251 for the second plurality of FETs 203. Accordingly, it will be appreciated that the first plurality of FETs 201 and the second plurality of FETs 203 are arranged substantially as mirror images with the first plurality of source contacts 250 being arranged adjacent the second plurality of source contacts 251 at a center region of the first column and second column. The second plurality of FETs 203 also includes drain contacts 261, a first gate 212, a second gate 214 and a resurf portion 216. The resurf portion 216 is disposed partially over the first gate and over the second gate 214 and extends to the drain contacts 261. An implanted center well region 270 is formed in the center region (P+ well for nFETs and N+ well for pFETs) and configured to make electrical ohmic connection to the well of the composite FET. It will be appreciated also that the P+ implants are used for pFET source/drain implant or N+ implants are used for nFET source/drain implant. In this illustrated configuration each of the gates 202, 204, 212 and 214 are coupled together at the ends of the columns.

However, it will be appreciated that the gates 202, 204, 212 and 214 may be coupled together at only one end and still be electrically coupled in common. A reference line A-A′ is illustrated and used for designating the cross-sectional view illustrated in FIG. 2B.

FIG. 2B illustrates a cross-sectional view of apparatus 200 at line A-A′ in FIG. 2A in accordance with one or more aspects of the disclosure. It will be appreciated that the configuration of each FET is similar to the FET discussed in relation to FIG. 1, so for brevity, all elements of each FET will not be discussed. As illustrated, the FET 201a from the first plurality of FETs 201 has a drain contact 260, a first gate 202, a second gate 204, and a resurf portion 206. The resurf portion 206 is disposed partially over the first gate 202, over the second gate 204 and in some aspects extends to the drain contact 260. The source contact 250 is adjacent source contact 251 of the FET 203a from the second plurality of FETs 203. Additionally, the FET 203a includes drain contact 261, a first gate 212, a second gate 214 and a resurf portion 216. The resurf portion 216 is disposed partially over the first gate 212, over the second gate 214 in some aspects extends to the drain contacts 261. The drain contact 260 is coupled to a drain region 262 with N+ implants in the body layer 220. The drain contact 261 is coupled to a drain region 263 with N+ implants in the body layer 220. Source contacts 250 and 251 have a common source region 252 with N+ implants in the body layer 220. A drift region 221 in the body layer 220 at least partially overlaps the first gate 202 of FET 201a. Likewise, a drift region 222 in the body layer 220 at least partially overlaps the first gate 214 of FET 203a.

FIG. 2C illustrates a partial top view of an apparatus 200 including a plurality of FETs in accordance with one or more aspects of the disclosure. The apparatus 200 can have a first plurality of FETs 201 arranged in a first column and a second plurality of FETs 203 arranged in a second column. The configuration is the same as FIG. 2A, so similar details will be omitted. In this illustration, a first body tap 281 extends from the first gate 202 to the center well region 270. The first body tap 282 is used as a body to source coupling for the first plurality of FETs 201. A second body tap 282 extends from the first gate 212 to the center well region 270 formed in the center of the first column and second column. The second body tap 282 is used as a body to source coupling for the second plurality of FETs 203. In this configuration, the FETs are three terminal devices including gate, source, drain terminals (contacts), with the body to source being internally coupled via first body tap 281 and second body tap 282. A reference line B-B′ is illustrated and used for designating the cross-sectional view illustrated in FIG. 2D.

FIG. 2D illustrates a cross-sectional view of apparatus 200 at line B-B′ in FIG. 2C in accordance with one or more aspects of the disclosure. It will be appreciated that the configuration of each FET is similar to the FET discussed in relation to FIG. 1 and FIG. 2B, so for brevity, all elements of each FET will not be discussed. As illustrated, the FET 201b from the first plurality of FETs 201 has a first gate 202, a second gate 204, and a resurf portion 206. The resurf portion 206 is disposed partially over the first gate and over the second gate 204. The FET 203b, form the second plurality of FETs 203, includes a first gate 212, a second gate 214 and a resurf portion 216. The resurf portion 216 is disposed partially over the first gate and over the second gate 214. The second body tap 282 extends from the first gate 212 of FET 203b to the center well region 270 (in this illustration a P+ well) in the body layer 220. A drift region 221 in the body layer 220 at least partially overlaps the first gate 202 of FET 201b. Likewise, a drift region 222 in the body layer 220 at least partially overlaps the first gate 214 of FET 203b.

FIG. 2E illustrates a partial top view of an apparatus 240 including a plurality of FETs in accordance with one or more aspects of the disclosure. The apparatus 240 can have a first plurality of FETs 241 arranged in a first column and a second plurality of FETs 243 arranged in a second column. The configuration and most elements of are similar to FIG. 2A, so similar aspects will be omitted or not discussed in detail. In this illustration, a first body tap 281 extends from the first gate 202 to the center well region 270. The first body tap 281 is used as a body to source coupling for the first plurality of FETs 241. A second body tap 282 extends from the first gate 212 to the center well region 270 formed in the center of the first column and second column. The second body tap 282 is used as a body to source coupling for the second plurality of FETs 243. The illustrated configuration differs from the prior configurations in that there are additional body contacts (e.g., 283, 284) coupling the second gates (204 and 214) of the first and second plurality of FETs (241 and 243). These additional body tap configurations will be discussed further below. Also, the illustrated configuration differs from the prior configurations in that there are additional secondary body taps (291, 292, 293 and 294) coupling the second gates (204 and 214) of the first and second plurality of FETs (241 and 243). For example, in some aspects, only two secondary body taps may be used. For example, a first secondary body tap 291 is configured to couple between the second gate 204 of the first plurality of FETs 241 and the center well region 270. A second secondary body tap 292 is configured to couple between the second gate 214 of the second plurality of FETs 243 and the center well region 270. It will be appreciated that further aspect one or more additional secondary body taps (e.g., 293) can be used to couple the second gate 204 of the first plurality of FETs 241 and the center well region 270 and one or more additional secondary body taps (e.g., 294) can be used to couple between the second gate 214 of the second plurality of FETs 243 and the center well region 270. For the second gate to be connected to body, the first gates (202 and 212) of each of the FETs (241 and 243) is broken in portions 295. However, at the metal 1 level (or other metal layer coupled to the gates) the broken first gates are still electrically connected to the same potential. Accordingly, the gates perform electrically, similar to the gates without the broken portions 295. Additionally, in this configuration, the FETs are three terminal devices including gate, source, and drain terminals (contacts). A reference line C-C′ is illustrated and used for designating the cross-sectional view illustrated in FIG. 2F.

FIG. 2F illustrates a cross-sectional view of apparatus 240 at line C-C′ in FIG. 2E in accordance with one or more aspects of the disclosure. It will be appreciated that the configuration of each FET is similar to the FET discussed in relation to FIG. 1 and FIG. 2B, so for brevity, all elements of each FET will not be discussed. As illustrated, the FET 241a from the first plurality of FETs 241 has a second gate 204, and a resurf portion 206. The resurf portion 206 is disposed partially over the first gate and over the second gate 204. In this portion the first gate, was broken as discussed above, to allow for the body tap 291 to extend from the second gate 204 of FET 241a to the center well region 270 (in this illustration a P+ well). The FET 243a, from the second plurality of FETs 243, includes a first gate 212, a second gate 214, a resurf portion 216, source contact 251 and drain contact 261. The resurf portion 216 is disposed partially over the first gate and over the second gate 214, partially over the first gate 212 and extends to the drain contact 261. A drift region 221 in the body layer 220 at least partially overlaps the second gate 204 of FET 241a. Likewise, a drift region 222 in the body layer 220 at least partially overlaps the second gate 214 of FET 243a.

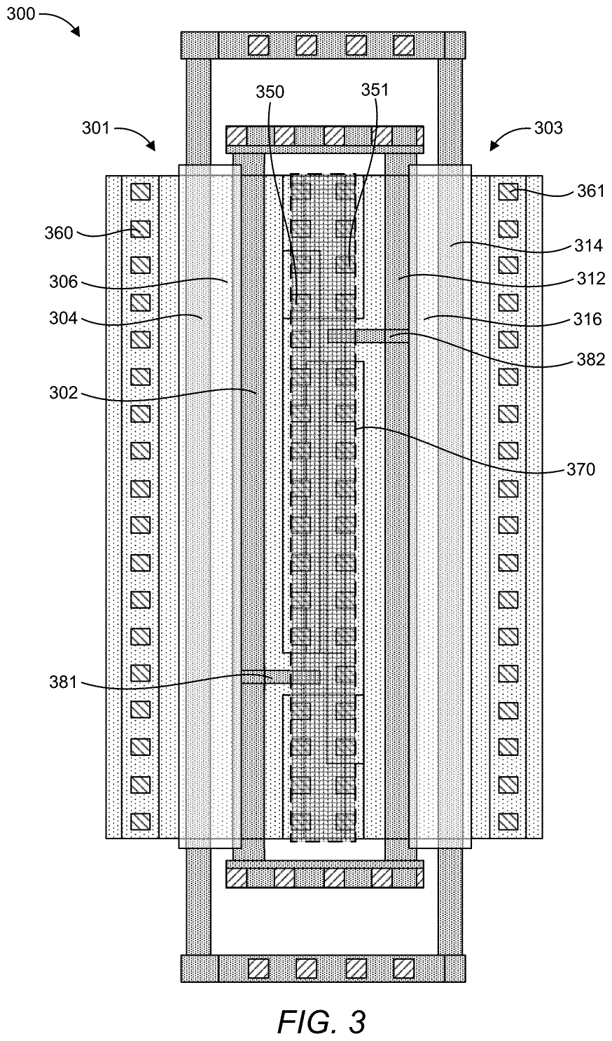

FIG. 3 illustrates a partial top view of an apparatus 300 including a plurality of FETs in accordance with one or more aspects of the disclosure. The apparatus 300 can have a first plurality of FETs 301 arranged in a first column and a second plurality of FETs 303 arranged in a second column. The first plurality of FETs 301 includes drain contacts 360, a first gate 302, a second gate 304, and a resurf portion 306. The resurf portion 306 is disposed partially over the first gate and over the second gate 304 and extends to the drain contacts 360. The first plurality of FETs 301 further includes a plurality of source contacts 350. In the illustrated arrangement, the source contacts 350 of the first plurality of FETs 301 are adjacent a second plurality of source contacts 351 for the second plurality of FETs 303. Accordingly, it will be appreciated that the first plurality of FETs 301 and the second plurality of FETs 303 are arranged substantially as mirror images with the first plurality of source contacts 350 being arranged adjacent the second plurality of source contacts 351 at a center region of the first column and second column. The second plurality of FETs 303 also includes drain contacts 361, a first gate 312, a second gate 314 and a resurf portion 316. The resurf portion 316 is disposed partially over the first gate and over the second gate 314 and extends to the drain contacts 361. An implanted center well region 370 (P+ well for nFETs or N+ well for pFETs) is formed in the center region. In this illustration, a first body tap 381 extends from the first gate 302 to the center well region 370. The first body tap 381 is used as a body to source coupling for the first plurality of FETs 301. A second body tap 382 extends from the first gate 312 to the center well region 370 formed in the center of the first column and second column. The second body tap 382 is used as a body to source coupling for the second plurality of FETs 303.

In this illustrated configuration of FIG. 3, each of the first gates 302 and 312 are coupled together at the ends of the columns. Additionally, each of the second gates 304 and 314 are coupled together at the ends of the columns. However, it will be appreciated that the first gates 302 and 312 may be coupled together at only one end and still be electrically coupled in common. Likewise, it will be appreciated that the second gates 304 and 314 may be coupled together at only one end and still be electrically coupled in common. In the illustrated configuration, it will be appreciated that the first gates 302 and 312 may be controlled independent from the second gates 304 and 314. In some aspects, this configuration allows for the second gates 304 and 314 to have separate connection as well as threshold voltage to allow the drift region electric field control (resurf control). The first (primary) gates (302, 312) and second (secondary) gate (304, 314) can be formed of different materials, such as poly and metal etc. and with different Vt materials. Resurf portions 306, 316 can be made of materials such as SiN, SiO2, metals, and implants. The second gates (304 and 314) allow dynamic control during operation.

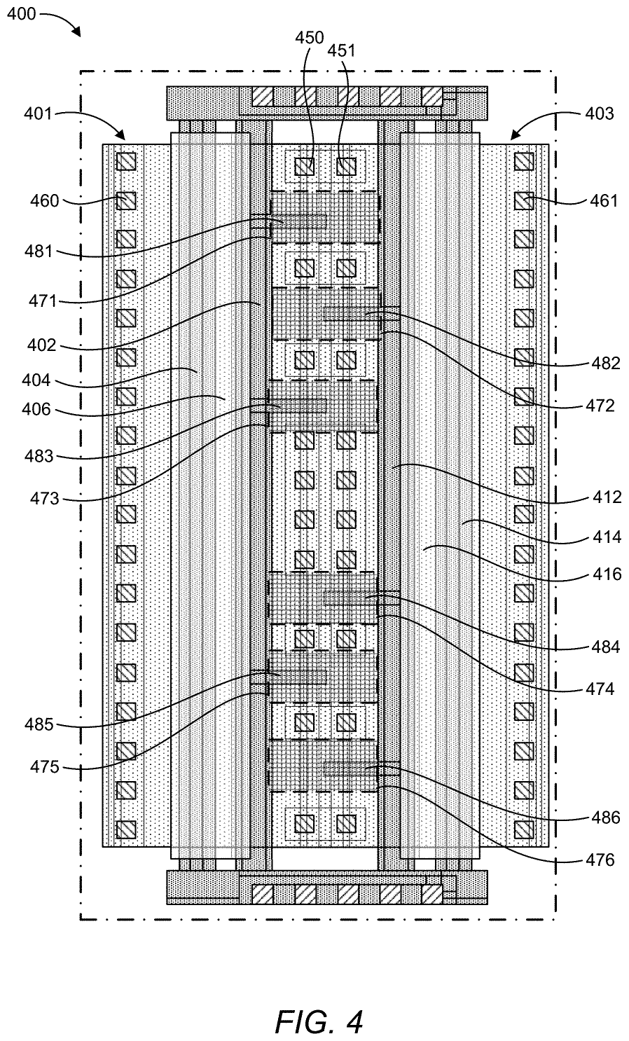

FIG. 4 illustrates a partial top view of an apparatus 400 including a plurality of FETs in accordance with one or more aspects of the disclosure. The apparatus 400 can have a first plurality of FETs 401 arranged in a first column and a second plurality of FETs 403 arranged in a second column. The first plurality of FETs 401 includes drain contacts 460, a first gate 402, a second gate 404, and a resurf portion 406. The resurf portion 406 is disposed partially over the first gate and over the second gate 404 and extends to the drain contacts 460. The first plurality of FETs 401 further includes a plurality of source contacts 450. In the illustrated arrangement, the source contacts 450 of the first plurality of FETs 401 are adjacent a second plurality of source contacts 451 for the second plurality of FETs 403. Accordingly, it will be appreciated that the first plurality of FETs 401 and the second plurality of FETs 403 are arranged substantially as mirror images with the first plurality of source contacts 450 being arranged adjacent the second plurality of source contacts 451 at a center region of the first column and second column. The second plurality of FETs 403 also includes drain contacts 461, a first gate 412, a second gate 414 and a resurf portion 416. The resurf portion 416 is disposed partially over the first gate and over the second gate 414 and extends to the drain contacts 461.

In this illustrated configuration of FIG. 4, a plurality of implanted center well regions are formed in the center region (P+ wells for nFETs or N+ wells for pFETs). In nFET designs, the center well regions will have a P+ region body contact sandwiched between N+ implants for each source region. In pFET designs, the center well regions will have a N+ region body contact sandwiched between P+ implants. In this configuration, the increased body taps provide for better body pick up, lower the body current and to keep the source/body potential similar. In this configuration, a first body tap 481 extends from the first gate 402 to a first center well region 471. The first body tap 481 is used as a body to source coupling for the first plurality of FETs 401. A second body tap 482 extends from the first gate 412 to a second center well region 472. The second body tap 482 is used as a body to source coupling for the second plurality of FETs 403. A third body tap 483 extends from the first gate 402 to a third center well region 473. The third body tap 483 is used as a body to source coupling for the first plurality of FETs 401. A fourth body tap 484 extends from the first gate 412 to a fourth center well region 474. The fourth body tap 484 is used as a body to source coupling for the second plurality of FETs 403. A fifth body tap 485 extends from the first gate 402 to a fifth center well region 475. The fifth body tap 485 is used as a body to source coupling for the first plurality of FETs 401. A sixth body tap 486 extends from the first gate 412 to a sixth center well region 476. The sixth body tap 486 is used as a body to source coupling for the second plurality of FETs 403. It will be appreciated that the number of body taps provides a tradeoff between the source efficiency and the source to gate capacitance. More taps lead to lower source efficiency and higher gate to source capacitance.

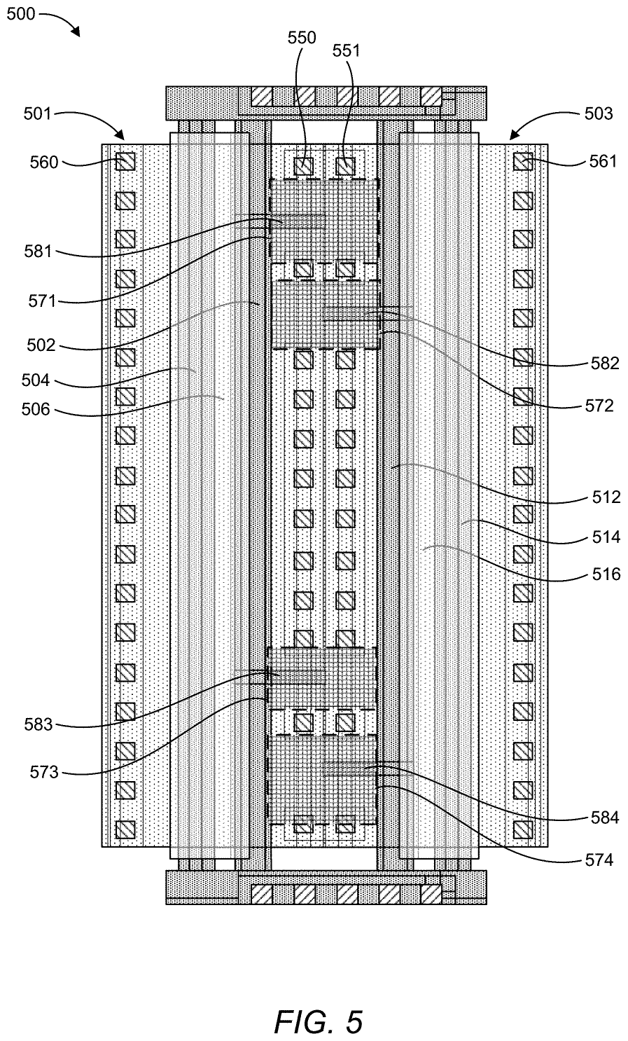

FIG. 5 illustrates a partial top view of an apparatus 500 including a plurality of FETs in accordance with one or more aspects of the disclosure. The apparatus 500 can have a first plurality of FETs 501 arranged in a first column and a second plurality of FETs 503 arranged in a second column. The first plurality of FETs 501 includes drain contacts 560, a first gate 502, a second gate 504, and a resurf portion 506. The resurf portion 506 is partially over the first gate and disposed over the second gate 504 and extends to the drain contacts 560. The first plurality of FETs 501 further includes a plurality of source contacts 550. In the illustrated arrangement, the source contacts 550 of the first plurality of FETs 501 are adjacent a second plurality of source contacts 551 for the second plurality of FETs 503. Accordingly, it will be appreciated that the first plurality of FETs 501 and the second plurality of FETs 503 are arranged substantially as mirror images with the first plurality of source contacts 550 being arranged adjacent the second plurality of source contacts 551 at a center region of the first column and second column. The second plurality of FETs 503 also includes drain contacts 561, a first gate 512, a second gate 514 and a resurf portion 516. The resurf portion 516 is disposed partially over the first gate 512, over the second gate 514 and extends to the drain contacts 561.

In this illustrated configuration of FIG. 5, a plurality of implanted well regions are formed in the center region (P+ wells for nFETs or N+ wells for pFETs). In this illustration, a first body tap 581 extends from the first gate 502 to a first center well region 571. The first body tap 581 is used as a body to source coupling for the first plurality of FETs 501. A second body tap 582 extends from the first gate 512 to a second center well region 572. The second body tap 582 is used as a body to source coupling for the second plurality of FETs 503. A third body tap 583 extends from the first gate 502 to a third center well region 573. The third body tap 583 is used as a body to source coupling for the first plurality of FETs 501. A fourth body tap 584 extends from the first gate 512 to a fourth center well region 574. The fourth body tap 584 is used as a body to source coupling for the second plurality of FETs 503.

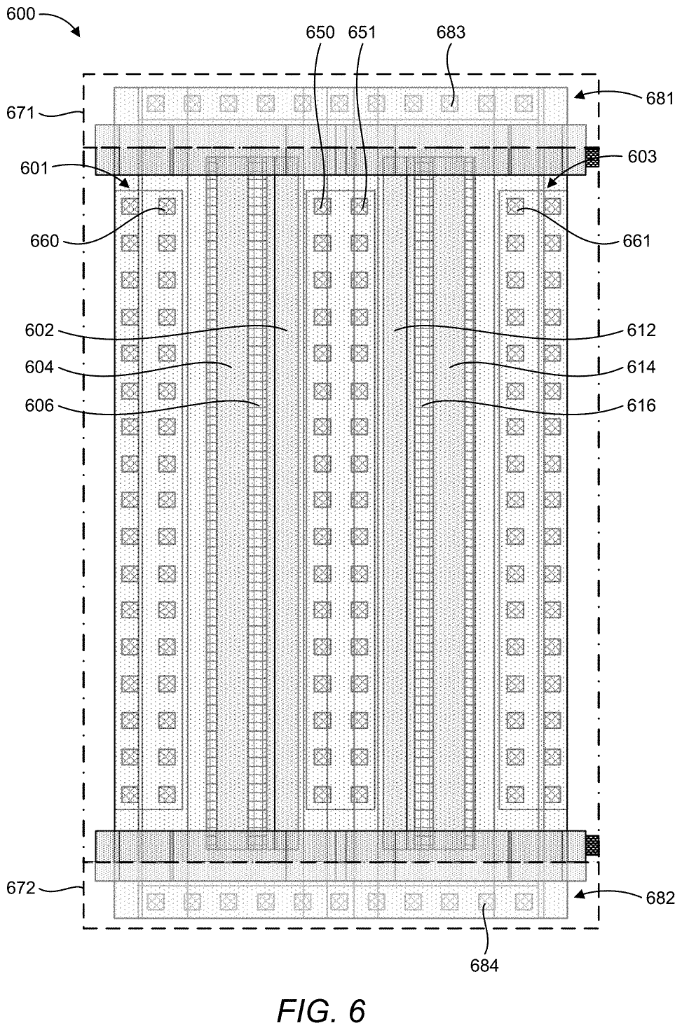

FIG. 6 illustrates a partial top view of an apparatus 600 including a plurality of FETs in accordance with one or more aspects of the disclosure. The apparatus 600 can have a first plurality of FETs 601 arranged in a first column and a second plurality of FETs 603 arranged in a second column. The first plurality of FETs 601 includes drain contacts 660, a first gate 602, a second gate 604, and a resurf portion 606. The resurf portion 606 is disposed partially over the first gate and over the second gate 604 and extends to the drain contacts 660. The first plurality of FETs 601 further includes a plurality of source contacts 650. In the illustrated arrangement, the source contacts 650 of the first plurality of FETs 601 are adjacent a second plurality of source contacts 651 for the second plurality of FETs 603. Accordingly, it will be appreciated that the first plurality of FETs 601 and the second plurality of FETs 603 are arranged substantially as mirror images with the first plurality of source contacts 650 being arranged adjacent the second plurality of source contacts 651 at a center region of the first column and second column. The second plurality of FETs 603 also includes drain contacts 661, a first gate 612, a second gate 614 and a resurf portion 616. The resurf portion 616 is disposed partially over the first gate and over the second gate 614 and extends to the drain contacts 661.

In this illustrated configuration of FIG. 6, generally referred to as a “H-gate” configuration, a first well region 671 (P+ wells for nFETs or N+ wells for pFETs) is formed at a first end of the columns. a first body tap region 681 is located in the first well region 671 at the first end of the columns. The first body tap region 681 includes a plurality of contacts 683. A second well region 672 (P+ wells for nFETs or N+ wells for pFETs) is formed at a second end of the columns, opposite the first end. A second body tap region 682 is located in the second well region 672 at the second end of the columns. The second body tap region 682 includes a plurality of contacts 684. In this configuration, the FETs are four terminal devices including gate, source, drain and body terminals (contacts).

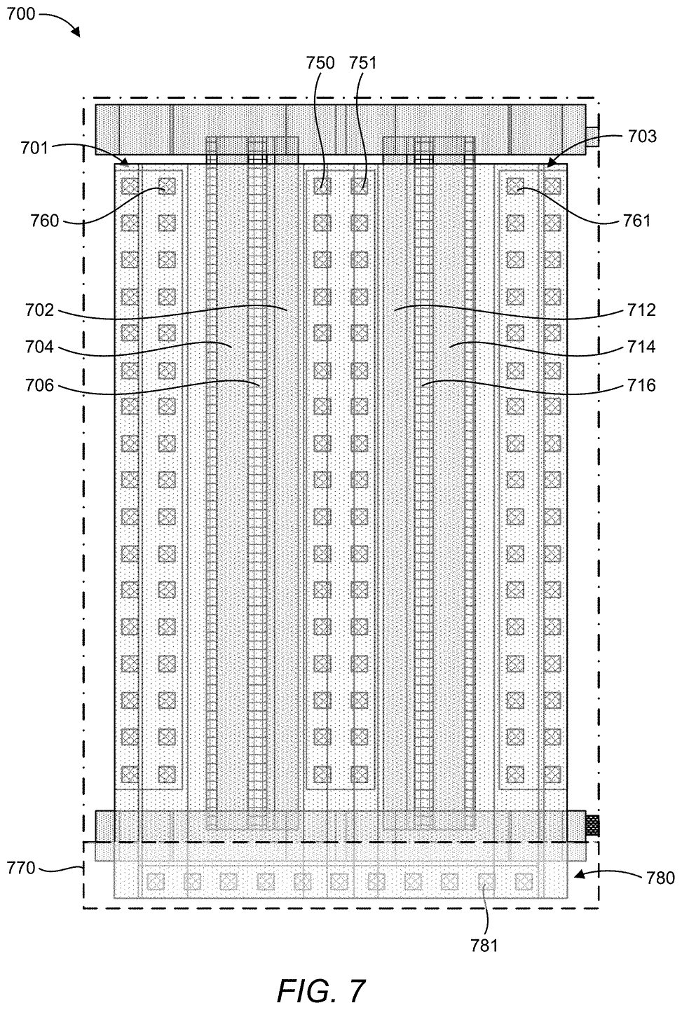

FIG. 7 illustrates a partial top view of an apparatus 700 including a plurality of FETs in accordance with one or more aspects of the disclosure. The apparatus 700 can have a first plurality of FETs 701 arranged in a first column and a second plurality of FETs 703 arranged in a second column. The first plurality of FETs 701 includes drain contacts 760, a first gate 702, a second gate 704,and a resurf portion 706. The resurf portion 706 is disposed partially over the first gate and over the second gate 704 and extends to the drain contacts 760. The first plurality of FETs 701 further includes a plurality of source contacts 750. In the illustrated arrangement, the source contacts 750 of the first plurality of FETs 701 are adjacent a second plurality of source contacts 751 for the second plurality of FETs 703. Accordingly, it will be appreciated that the first plurality of FETs 701 and the second plurality of FETs 703 are arranged substantially as mirror images with the first plurality of source contacts 750 being arranged adjacent the second plurality of source contacts 751 at a center region of the first column and second column. The second plurality of FETs 703 also includes drain contacts 761, a first gate 712, a second gate 714 and a resurf portion 716. The resurf portion 716 is disposed partially over the first gate and over the second gate 714 and extends to the drain contacts 761.

In this illustrated configuration of FIG. 7, generally referred to as a “T-gate” configuration, an implanted well region 770 (P+ wells for nFETs or N+ wells for pFETs) is located at a first end of the columns. In this illustration, a body tap 780 is located in the well region 770 at the first end of the columns and includes a plurality of contacts 781. It will be appreciated that the well region 770, body tap 780 and plurality of contacts 781, may be located at either end of the columns and this configuration is not limited to the illustrated example provided. In this configuration, the FETs are also four terminal devices including gate, source, drain and body terminals (contacts).

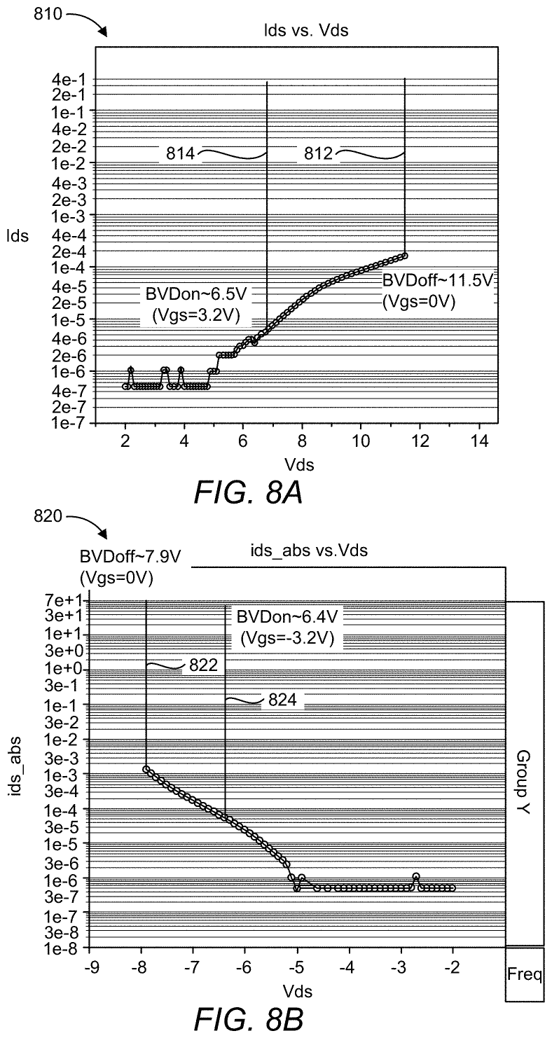

FIG. 8A is a graph illustrating the breakdown voltage of a nFET according to one or more aspects of the disclosure. The graph 810 is for a nFET with the voltage drain-source (Vds) plotted on the x-axis and the current drain-source (Ids) plotted on the y-axis. A first breakdown voltage plot 812 is for the off condition, with the gate voltage (Vgs) being equal to zero volts (0V). In this example, the breakdown voltage in the nFET off state occurs at approximately 11.5 Vds. A second breakdown voltage plot 814 is for the on condition, with the gate voltage (Vgs) being equal to 3.2V. In this example, the breakdown voltage in the nFET on state occurs at approximately 6.5 Vds. Accordingly, it will be appreciated that off state breakdown voltage is greater than the on state breakdown voltage. Further, when compared to the conventional FET designs, both the on state and off state breakdown voltages are higher, which improves the FET's reliability.

FIG. 8B is a graph illustrating the breakdown voltage of a pFET according to one or more aspects of the disclosure. The graph 820 is for a pFET with the voltage drain-source (Vds) plotted on the x-axis and the current drain-source (Ids) in absolute values is plotted on the y-axis. A first breakdown voltage plot 822 is for the off condition, with the gate voltage (Vgs) being equal to zero volts (0V). In this example, the breakdown voltage in the pFET off state occurs at approximately −7.9 Vds. A second breakdown voltage plot 824 is for the on condition, with the gate voltage (Vgs) being equal to 3.2V. In this example, the breakdown voltage in the pFET on state occurs at approximately −6.4 Vds. Accordingly, it will be appreciated that off state breakdown voltage is greater (in absolute value) than the on state breakdown voltage. Further, when compared to the conventional FET designs, both the on state and off state breakdown voltages (in absolute values) are higher, which improves the FET's reliability.

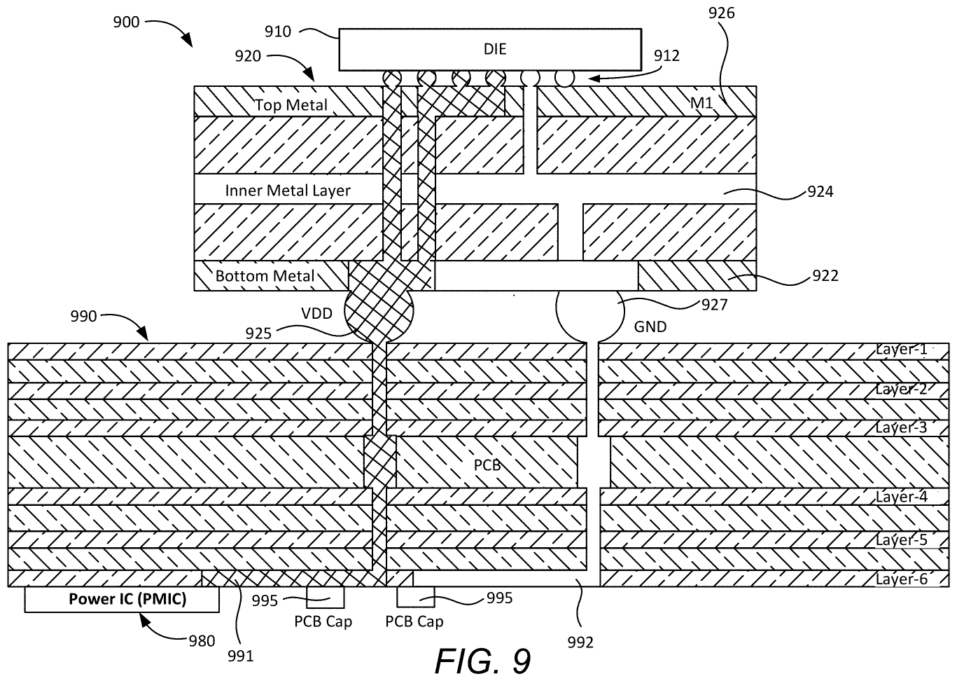

FIG. 9 illustrates components of an integrated device 900 according to one or more aspects of the disclosure. Regardless of the various configurations of the FET devices discussed above, it will be appreciated that the FET devices can be integrated into various devices. For example, the apparatuses (e.g., 200, 240, 300, 400, 500, 600 and 700) discussed above in some aspects may be the die 910 (e.g., RFFE, pre-amplifier, etc.) which includes the FETs and FET layouts discussed herein. Additionally, the apparatuses (e.g., 200, 240, 300, 400, 500, 600 and 700) discussed above, in some aspects, may be the power IC 980 which includes the FETs and FET layouts discussed herein (e.g., battery switches, power switches, etc.). Further, the apparatuses (e.g., 200, 300, 400, 500, 600 and 700) discussed above in some aspects may be the integrated device 900, as various components may include the FETs and FET layouts discussed herein.

As illustrated, the package 920 may be configured to couple the die 910 to a PCB 990. The PCB 990 is also coupled to a power supply 980 (e.g., a power management integrated circuit (PMIC)), which allows the package 920 and the die 910 to be electrically coupled to the PMIC 980. Specifically, one or more power supply (VDD) lines 991 and one or more ground (GND) lines 992 may be coupled to the PMIC 980 to distribute power to the PCB 990, package 920 via VDD BGA pin 925 and GND BGA pin 927 and to the die 910 via die bumps 912. The die bumps 912 may include plated UBMs of various sizes and pitches, which can be coupled to the top metal layer 926 (e.g., M1 layer), and through one or more inner metal layers 924 and a bottom metal layer 922, which is coupled to the BGA pins of package 920. The VDD line 991 and GND line 992 each may be formed from traces, shapes or patterns in one or more metal layers of the PCB 990 (e.g., layers 1-6) coupled by one or more vias through insulating layers separating the metal layers 1-6 in the PCB 990. The PCB 990 may have one or more PCB capacitors (PCB cap) 995 that can be used to condition the power supply signals, as is known to those skilled in the art. Additional connections and devices may be coupled to and/or pass through the PCB 990 to the package 920 via one or more additional BGA pins (not illustrated) on the package 920. It will be appreciated that the illustrated configuration and descriptions are provided merely to aid in the explanation of the various aspects disclosed herein. For example, the PCB 990 may have more or less metal and insulating layers, there may be multiple lines providing power to the various components, etc. Accordingly, the forgoing illustrative examples and associated figures should not be construed to limit the various aspects disclosed and claimed herein

In accordance with the various aspects disclosed herein, at least one aspect includes an apparatus (e.g., 200, 240, 300, 400, 500, 600, 700 and 900) including: a field-effect transistor (FET) (e.g., 100, 201, 202, etc.) having a source contact (e.g., 150, 250, 251) coupled to a body layer (e.g., 120, 220). The FET further includes a drain contact (e.g., 160, 260, 261) coupled to the body layer. The FET further includes a first gate (e.g., 102, 202, 212) coupled to the body layer between the source contact and the drain contact. The FET further includes a second gate (e.g., 104, 204, 214) coupled to the body layer between the source contact and the drain contact. The FET further includes a drift region (e.g., 121, 221, 222) in the body layer, wherein the second gate at least partially overlaps the drift region; and a resurf portion (e.g., 106, 205, 216) disposed over the second gate.

Among the various technical advantages the various aspects disclosed provide, in at least some aspects, the second gate allows for control of the electric field in the drift region to improve the breakdown voltage (BVD) and on resistance (Ron). In some aspects, a separate connection to the second gate allows for dynamic control of the electric field in the drift region during operation. Other aspects allow for the drain side halo implant to be different from source side to allow for better BVD and Ron trade-off. The resurf portion/salicide block allows for holding the gate-drain voltage (Vgd) (resurf to reduce electric field and provide margin to time dependent dielectric breakdown (TDDB) and gate-induced drain leakage (GIDL)). Further, in some aspects, the increased body taps provide for better body pick up, lower the body current and keeping the source/body potential similar. Other technical advantages will be recognized from various aspects disclosed herein and these technical advantages are merely provided as examples and should not be construed to limit any of the various aspects disclosed herein.

In order to fully illustrate aspects of the design of the present disclosure, methods of fabrication are presented. Other methods of fabrication are possible and discussed fabrication methods are presented only to aid understanding of the concepts disclosed herein.

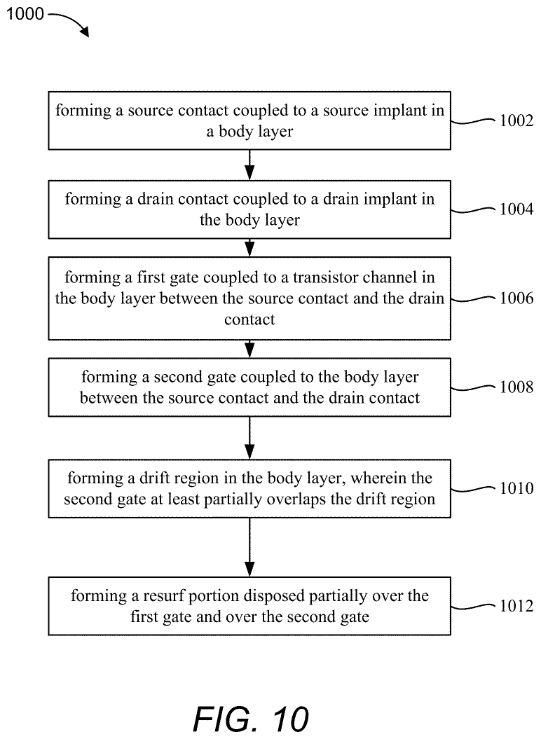

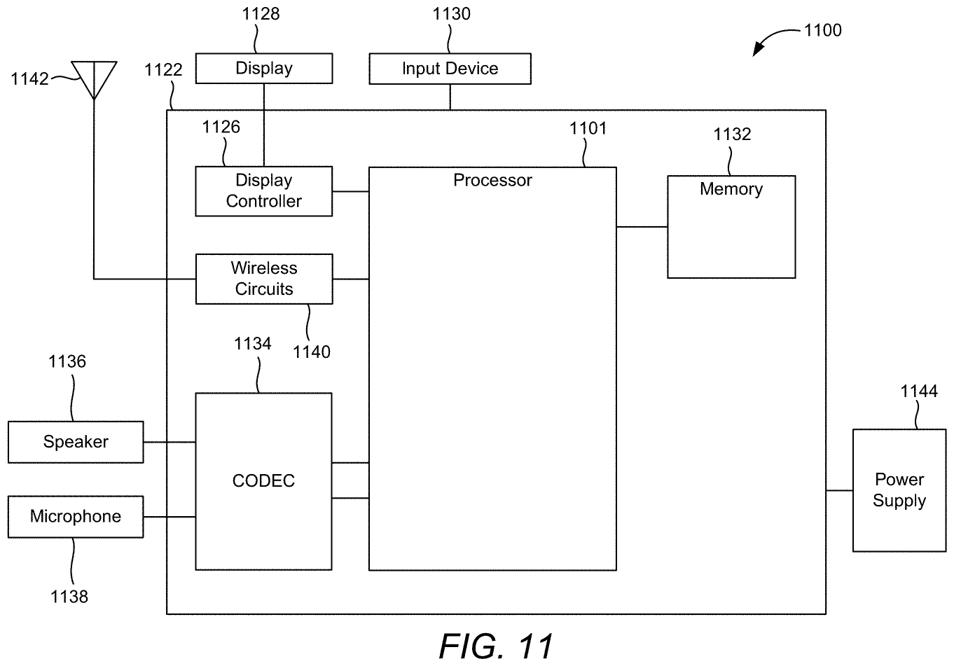

It will be appreciated from the foregoing that there are various methods for fabricating the various apparatuses disclosed herein. FIG. 10 illustrates a flowchart of a method 1000 for fabricating an apparatus including a field-effect transistor (FET). The method includes, in block 1002, forming a source contact coupled to a body layer. The method further includes, in block 1004, forming a drain contact coupled to the body layer. The method further includes, in block 1006, forming a first gate coupled to the body layer between the source contact and the drain contact. The method further includes, in block 1008, forming a second gate coupled to the body layer between the source contact and the drain contact. The method further includes, in block 1010, forming a drift region in the body layer, wherein the second gate at least partially overlaps the drift region. The method further includes, in block 1012, forming a resurf portion disposed partially over the first gate and over the second gate. Accordingly, it will be appreciated from the foregoing disclosure that additional processes for fabricating the various aspects disclosed herein will be apparent to those skilled in the art and a literal rendition of the processes discussed above will not be provided or illustrated in the included drawings.

It will be appreciated that the foregoing fabrication process was provided merely as general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

FIG. 11 illustrates an exemplary mobile device in accordance with some examples of the disclosure. Referring now to FIG. 11, a block diagram of a mobile device that is configured according to exemplary aspects is depicted and generally designated mobile device 1100. In some aspects, mobile device 1100 may be configured as a wireless communication device. As shown, mobile device 1100 includes processor 1101. Processor 1101 may be communicatively coupled to memory 1132 over a link, which may be a die-to-die or chip-to-chip link. Mobile device 1100 also includes display 1128 and display controller 1126, with display controller 1126 coupled to processor 1101 and to display 1128.

In some aspects, FIG. 11 may include coder/decoder (CODEC) 1134 (e.g., an audio and/or voice CODEC) coupled to processor 1101; speaker 1136 and microphone 1138 coupled to CODEC 1134; and wireless circuits 1140 (which may include a modem, RF circuitry, etc. which may be implemented using one or more FETs/FET layouts, as disclosed herein) coupled to wireless antenna 1142 and to processor 1101.

In a particular aspect, where one or more of the above-mentioned blocks are present, processor 1101, display controller 1126, memory 1132, CODEC 1234, and wireless circuits 1140 can be included in a system-in-package or system-on-chip device 1122 which may be implemented in whole or part using the flip-chip techniques disclosed herein. Input device 1130 (e.g., physical or virtual keyboard), power supply 1144 (e.g., battery), display 1128, input device 1130, speaker 1136, microphone 1138, wireless antenna 1142, and power supply 1144 may be external to system-on-chip device 1122 and may be coupled to a component of system-on-chip device 1122, such as an interface or a controller.

It should be noted that although FIG. 11 depicts a mobile device 1100, processor 1101 and memory 1132 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

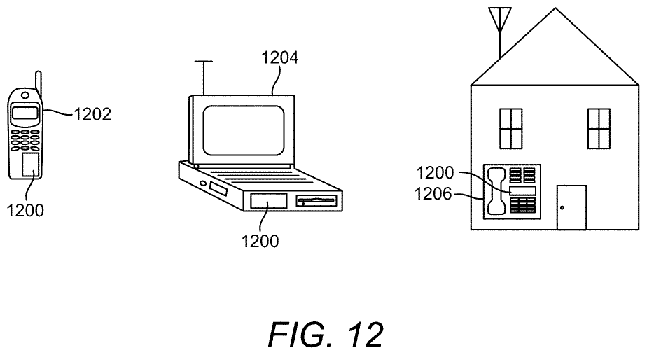

FIG. 12 illustrates various electronic devices that may be integrated with any of the aforementioned integrated device or semiconductor device in accordance with various examples of the disclosure. For example, a mobile phone device 1202, a laptop computer device 1204, and a fixed location terminal device 1206 may each be consider generally user equipment (UE) and may include one or more FETs devices 1200 as described herein. The one or more FETs 1200 may be, for example, any of the integrated circuits, dies, integrated devices, integrated device packages, integrated circuit devices, device packages, integrated circuit (IC) packages, package-on-package devices including one or more FETs described herein. The devices 1202, 1204, 1206 illustrated in FIG. 12 are merely exemplary. Other electronic devices may also feature the FET device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into one or more computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into various integrated devices. These integrated devices may then be employed in the various devices described herein.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-12 may be rearranged and/or combined into a single component, process, feature or function or incorporated in several components, processes, or functions. Additional elements, components, processes, and/or functions may also be added without departing from the disclosure. It should also be noted that FIGS. 1-12 and corresponding description in the present disclosure are not limited to dies and/or ICs. In some implementations, FIGS. 1-12 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Further, those of skill in the art will appreciate that the various illustrative logical blocks, modules, circuits, and algorithm actions described in connection with the examples disclosed herein may be implemented as electronic hardware, computer software, or combinations of both. To clearly illustrate this interchangeability of hardware and software, various illustrative components, blocks, modules, circuits, and actions have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer or an electronic circuit. In some examples, some or a plurality of the most important method actions can be performed by such an apparatus.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or a plurality of claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an insulator and a conductor). Furthermore, it is also intended that aspects of a clause can be included in any other independent clause, even if the clause is not directly dependent on the independent clause.

Implementation examples are described in the following numbered clauses:

Clause 1. An apparatus comprising: a field-effect transistor (FET) comprising: a source contact coupled to a source implant in a body layer; a drain contact coupled to a drain implant in the body layer; a first gate coupled to a transistor channel in the body layer between the source contact and the drain contact; a second gate coupled to the body layer between the source contact and the drain contact; a drift region in the body layer, wherein the second gate at least partially overlaps the drift region; and a resurf portion disposed partially over the first gate and over the second gate.

Clause 2. The apparatus of clause 1, wherein the resurf portion extends to the drain contact.

Clause 3. The apparatus of clause 2, wherein the second gate is adjacent to the drain contact.

Clause 4. The apparatus of any of clauses 1 to 3, wherein the first gate is adjacent to the source contact and the second gate is adjacent to the drain contact.

Clause 5. The apparatus of any of clauses 1 to 4, wherein the first gate and the second gate are formed from a same material.

Clause 6. The apparatus of clause 5, wherein the same material comprises polysilicon.

Clause 7. The apparatus of any of clauses 1 to 4, wherein the first gate and the second gate are formed from different materials.

Clause 8. The apparatus of any of clauses 1 to 7, wherein the first gate and the second gate are separated by a distance on a range of 0.09-0.2 um.

Clause 9. The apparatus of any of clauses 1 to 8, wherein the body layer further comprises a first halo implant adjacent the source contact and a second halo implant adjacent the drain contact.

Clause 10. The apparatus of clause 9, wherein the first halo implant is different from the second halo implant.

Clause 11. The apparatus of any of clauses 9 to 10, wherein the body layer further comprises a third halo implant in the drift region.

Clause 12. The apparatus of any of clauses 1 to 11, wherein the first gate and the second gate are electrically coupled to a common connection.

Clause 13. The apparatus of any of clauses 1 to 11, wherein the first gate and the second gate are electrically coupled to separate connections.

Clause 14. The apparatus of any of clauses 1 to 13, further comprising a source extension region adjacent the source contact and a drain extension region adjacent the drain contact.

Clause 15. The apparatus of any of clauses 1 to 14, further comprising: a first plurality of FETs arranged in a first column; and a second plurality of FETs arranged in a second column.

Clause 16. The apparatus of clause 15, wherein: the first plurality of FETs comprises a first plurality of drain contacts and a first plurality of source contacts, the second plurality of FETs comprises a second plurality of drain contacts and a second plurality of source contacts, and the first plurality of FETs and the second plurality of FETs are arranged substantially as mirror images with the first plurality of source contacts being arranged adjacent the second plurality of source contacts at a center region between the first column and the second column.

Clause 17. The apparatus of clause 16, further comprising: a center well region disposed in the center region between the first column and the second column; a first body tap coupled between a first gate of the first plurality of FETs and the center well region; and a second body tap coupled between a first gate of the second plurality of FETs and the center well region.

Clause 18. The apparatus of clause 17, further comprising: a first secondary body tap coupled between a second gate of the first plurality of FETs and the center well region; and a second secondary body tap coupled between a second gate of the second plurality of FETs and the center well region.

Clause 19. The apparatus of any of clauses 16 to 18, further comprising: a plurality of center well regions disposed in the center region between the first column and the second column.

Clause 20. The apparatus of clause 19, wherein the plurality of center well regions comprises: a first center well region including a first body tap, wherein the first body tap is coupled to a first gate of the first plurality of FETs; a second center well region including a second body tap, wherein the second body tap is coupled to a first gate of the second plurality of FETs; a third center well region including a third body tap, wherein the third body tap is coupled to the first gate of the first plurality of FETs; and a fourth center well region including a fourth body tap, wherein the fourth body tap is coupled to the first gate of the second plurality of FETs.

Clause 21. The apparatus of clause 20, wherein the first center well region and the second center well region are located toward a first end of the first column and the second column, and wherein the third center well region and the fourth center well region are located toward a second end, opposite the first end, of the first column and the second column.

Clause 22. The apparatus of any of clauses 20 to 21, wherein the plurality of center well regions further comprises: a fifth center well region including a fifth body tap, wherein the fifth body tap is coupled to the first gate of the first plurality of FETs; and a sixth center well region including a sixth body tap, wherein the sixth body tap is coupled to the first gate of the second plurality of FETs.

Clause 23. The apparatus of clause 22, wherein the fifth center well region and the sixth center well region are located generally toward a center of the first column and the second column.

Clause 24. The apparatus of any of clauses 15 to 23, further comprising: a first well region disposed at a first end of the first column and the second column; and a first body tap region having a plurality of body contacts, wherein the first body tap region is disposed in the first well region.

Clause 25. The apparatus of clause 24, further comprising: a second well region disposed at a second end, opposite the first end, of the first column and the second column; and a second body tap region having a plurality of body contacts, wherein the second body tap region is disposed in the second well region.

Clause 26. The apparatus of any of clauses 1 to 25, wherein the apparatus is selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 27. A method for fabricating an apparatus including a field-effect transistor (FET), the method comprising: forming a source contact coupled to a source implant in a body layer; forming a drain contact coupled to a drain implant in the body layer; forming a first gate coupled to a transistor channel in the body layer between the source contact and the drain contact; forming a second gate coupled to the body layer between the source contact and the drain contact; forming a drift region in the body layer, wherein the second gate at least partially overlaps the drift region; and forming a resurf portion disposed partially over the first gate and over the second gate.

Clause 28. The method of clause 27, wherein the resurf portion extends to the drain contact.

Clause 29. The method of clause 28, wherein the second gate is adjacent to the drain contact.

Clause 30. The method of any of clauses 27 to 29, wherein the first gate is adjacent to the source contact and the second gate is adjacent to the drain contact.

Clause 31. The method of any of clauses 27 to 30, wherein the first gate and the second gate are separated by a distance on a range of 0.09-0.2 um.

Clause 32. The method of any of clauses 27 to 31, further comprising: implanting a first halo implant adjacent the source contact; and implanting a second halo implant adjacent the drain contact.

Clause 33. The method of clause 32, further comprising: implanting a third halo implant in the drift region.

Clause 34. The method of any of clauses 27 to 33, further comprising forming a source extension region adjacent the source contact; and forming a drain extension region adjacent the drain contact.

Clause 35. The method of any of clauses 27 to 34, further comprising: forming a first plurality of FETs in a first column; and forming a second plurality of FETs in a second column.

Clause 36. The method of clause 35, wherein: the first plurality of FETs comprises a first plurality of drain contacts and a first plurality of source contacts, the second plurality of FETs comprises a second plurality of drain contacts and a second plurality of source contacts, and the first plurality of FETs and the second plurality of FETs are arranged substantially as mirror images with the first plurality of source contacts being arranged adjacent the second plurality of source contacts at a center region between the first column and the second column.

Clause 37. The method of clause 36, further comprising: forming a center well region in the center region between the first column and the second column; forming a first body tap coupled between a first gate of the first plurality of FETs and the center well region; and forming a second body tap coupled between a first gate of the second plurality of FETs and the center well region.

Clause 38. The method of clause 37, further comprising: forming a first secondary body tap coupled between a second gate of the first plurality of FETs and the center well region; and forming a second secondary body tap coupled between a second gate of the second plurality of FETs and the center well region.

Clause 39. The method of any of clauses 36 to 38, further comprising: forming a plurality of center well regions disposed in the center region between the first column and the second column.

Clause 40. The method of clause 39, wherein forming the plurality of center well regions comprises: forming a first center well region including a first body tap, wherein the first body tap is coupled to a first gate of the first plurality of FETs; forming a second center well region including a second body tap, wherein the second body tap is coupled to a first gate of the second plurality of FETs; forming a third center well region including a third body tap, wherein the third body tap is coupled to the first gate of the first plurality of FETs; and forming a fourth center well region including a fourth body tap, wherein the fourth body tap is coupled to the first gate of the second plurality of FETs.

Clause 41. The method of clause 40, wherein the first center well region and the second center well region are located toward a first end of the first column and the second column, and wherein the third center well region and the fourth center well region are located toward a second end, opposite the first end, of the first column and the second column.

Clause 42. The method of any of clauses 35 to 41, further comprising: forming a first well region disposed at a first end of the first column and the second column; and forming a first body tap region having a plurality of body contacts, wherein the first body tap region is disposed in the first well region.

Clause 43. The method of clause 42, further comprising: forming a second well region disposed at a second end, opposite the first end, of the first column and the second column; and forming a second body tap region having a plurality of body contacts, wherein the second body tap region is disposed in the second well region.

Clause 44. The method of any of clauses 27 to 43, wherein the apparatus is selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. An apparatus comprising:
a field-effect transistor (FET) comprising:
a source contact coupled to a source implant in a body layer;
a drain contact coupled to a drain implant in the body layer;
a first gate coupled to a transistor channel in the body layer between the source contact and the drain contact;
a second gate coupled to the body layer between the source contact and the drain contact;
a drift region in the body layer, wherein the second gate at least partially overlaps the drift region; and
a resurf portion disposed partially over the first gate and over the second gate.

2. The apparatus of claim 1, wherein the resurf portion extends to the drain contact.

3. The apparatus of claim 2, wherein the second gate is adjacent to the drain contact.

4. The apparatus of claim 1, wherein the first gate is adjacent to the source contact and the second gate is adjacent to the drain contact.

5. The apparatus of claim 1, wherein the first gate and the second gate are formed from a same material.

6. The apparatus of claim 5, wherein the same material comprises polysilicon.

7. The apparatus of claim 1, wherein the first gate and the second gate are formed from different materials.

8. The apparatus of claim 1, wherein the first gate and the second gate are separated by a distance on a range of 0.09-0.2 um.

9. The apparatus of claim 1, wherein the body layer further comprises a first halo implant adjacent the source contact and a second halo implant adjacent the drain contact.

10. The apparatus of claim 9, wherein the first halo implant is different from the second halo implant.

11. The apparatus of claim 9, wherein the body layer further comprises a third halo implant in the drift region.

12. The apparatus of claim 1, wherein the first gate and the second gate are electrically coupled to a common connection.

13. The apparatus of claim 1, wherein the first gate and the second gate are electrically coupled to separate connections.

14. The apparatus of claim 1, further comprising a source extension region adjacent the source contact and a drain extension region adjacent the drain contact.

15. The apparatus of claim 1, further comprising:
a first plurality of FETs arranged in a first column; and
a second plurality of FETs arranged in a second column.

16. The apparatus of claim 15, wherein:
the first plurality of FETs comprises a first plurality of drain contacts and a first plurality of source contacts,
the second plurality of FETs comprises a second plurality of drain contacts and a second plurality of source contacts, and
the first plurality of FETs and the second plurality of FETs are arranged substantially as mirror images with the first plurality of source contacts being arranged adjacent the second plurality of source contacts at a center region between the first column and the second column.

17. The apparatus of claim 16, further comprising:
a center well region disposed in the center region between the first column and the second column;
a first body tap coupled between a first gate of the first plurality of FETs and the center well region; and
a second body tap coupled between a first gate of the second plurality of FETs and the center well region.

18. The apparatus of claim 17, further comprising:
a first secondary body tap coupled between a second gate of the first plurality of FETs and the center well region; and
a second secondary body tap coupled between a second gate of the second plurality of FETs and the center well region.

19. The apparatus of claim 16, further comprising:
a plurality of center well regions disposed in the center region between the first column and the second column.

20. The apparatus of claim 19, wherein the plurality of center well regions comprises:
a first center well region including a first body tap, wherein the first body tap is coupled to a first gate of the first plurality of FETs;
a second center well region including a second body tap, wherein the second body tap is coupled to a first gate of the second plurality of FETs;
a third center well region including a third body tap, wherein the third body tap is coupled to the first gate of the first plurality of FETs; and
a fourth center well region including a fourth body tap, wherein the fourth body tap is coupled to the first gate of the second plurality of FETs.

21. The apparatus of claim 20, wherein the first center well region and the second center well region are located toward a first end of the first column and the second column, and wherein the third center well region and the fourth center well region are located toward a second end, opposite the first end, of the first column and the second column.

22. The apparatus of claim 20, wherein the plurality of center well regions further comprises:
a fifth center well region including a fifth body tap, wherein the fifth body tap is coupled to the first gate of the first plurality of FETs; and
a sixth center well region including a sixth body tap, wherein the sixth body tap is coupled to the first gate of the second plurality of FETs.

23. The apparatus of claim 22, wherein the fifth center well region and the sixth center well region are located generally toward a center of the first column and the second column.

24. The apparatus of claim 15, further comprising:
a first well region disposed at a first end of the first column and the second column; and
a first body tap region having a plurality of body contacts, wherein the first body tap region is disposed in the first well region.

25. The apparatus of claim 24, further comprising:
a second well region disposed at a second end, opposite the first end, of the first column and the second column; and
a second body tap region having a plurality of body contacts, wherein the second body tap region is disposed in the second well region.

26. The apparatus of claim 1, wherein the apparatus is selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

27. A method for fabricating an apparatus including a field-effect transistor (FET), the method comprising:
forming a source contact coupled to a source implant in a body layer;
forming a drain contact coupled to a drain implant in the body layer;
forming a first gate coupled to a transistor channel in the body layer between the source contact and the drain contact;
forming a second gate coupled to the body layer between the source contact and the drain contact;
forming a drift region in the body layer, wherein the second gate at least partially overlaps the drift region; and
forming a resurf portion disposed partially over the first gate and over the second gate.

28. The method of claim 27, wherein the resurf portion extends to the drain contact.

29. The method of claim 28, wherein the second gate is adjacent to the drain contact.

30. The method of claim 27, wherein the first gate is adjacent to the source contact and the second gate is adjacent to the drain contact.

31. The method of claim 27, wherein the first gate and the second gate are separated by a distance on a range of 0.09-0.2 um.

32. The method of claim 27, further comprising:
implanting a first halo implant adjacent the source contact; and
implanting a second halo implant adjacent the drain contact.

33. The method of claim 32, further comprising:
implanting a third halo implant in the drift region.

34. The method of claim 27, further comprising
forming a source extension region adjacent the source contact; and
forming a drain extension region adjacent the drain contact.

35. The method of claim 27, further comprising:
forming a first plurality of FETs in a first column; and
forming a second plurality of FETs in a second column.

36. The method of claim 35, wherein:
the first plurality of FETs comprises a first plurality of drain contacts and a first plurality of source contacts,
the second plurality of FETs comprises a second plurality of drain contacts and a second plurality of source contacts, and
the first plurality of FETs and the second plurality of FETs are arranged substantially as mirror images with the first plurality of source contacts being arranged adjacent the second plurality of source contacts at a center region between the first column and the second column.

37. The method of claim 36, further comprising:
forming a center well region in the center region between the first column and the second column;
forming a first body tap coupled between a first gate of the first plurality of FETs and the center well region; and
forming a second body tap coupled between a first gate of the second plurality of FETs and the center well region.

38. The method of claim 37, further comprising:
forming a first secondary body tap coupled between a second gate of the first plurality of FETs and the center well region; and
forming a second secondary body tap coupled between a second gate of the second plurality of FETs and the center well region.

39. The method of claim 36, further comprising:
forming a plurality of center well regions disposed in the center region between the first column and the second column.

40. The method of claim 39, wherein forming the plurality of center well regions comprises:
forming a first center well region including a first body tap, wherein the first body tap is coupled to a first gate of the first plurality of FETs;
forming a second center well region including a second body tap, wherein the second body tap is coupled to a first gate of the second plurality of FETs;
forming a third center well region including a third body tap, wherein the third body tap is coupled to the first gate of the first plurality of FETs; and
forming a fourth center well region including a fourth body tap, wherein the fourth body tap is coupled to the first gate of the second plurality of FETs.

41. The method of claim 40, wherein the first center well region and the second center well region are located toward a first end of the first column and the second column, and wherein the third center well region and the fourth center well region are located toward a second end, opposite the first end, of the first column and the second column.

42. The method of claim 35, further comprising:
forming a first well region disposed at a first end of the first column and the second column; and
forming a first body tap region having a plurality of body contacts, wherein the first body tap region is disposed in the first well region.

43. The method of claim 42, further comprising:
forming a second well region disposed at a second end, opposite the first end, of the first column and the second column; and
forming a second body tap region having a plurality of body contacts, wherein the second body tap region is disposed in the second well region.

44. The method of claim 27, wherein the apparatus is selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
